(19) United States
(12) Patent Application Publication
(10) Pub. No.: US 2014/0167265 A1
(43) Pub. Date: Jun. 19, 2014

(54) METHODS OF FORMING A BI-LAYER CAP LAYER ON COPPER-BASED CONDUCTIVE STRUCTURES AND DEVICES WITH SUCH A CAP LAYER

(71) Applicant: GLOBAL FOUNDRIES INC., Grand Cayman (KY)

(72) Inventors: Dimitri R. Kioussis, Austin, TX (US); Youbo Lin, Ridgefield, CT (US); Zhiguo Sun, Halfmoon, NY (US)

(73) Assignee: GLOBALFOUNDRIES INC., Grand Cayman (KY)

(21) Appl. No.: 13/714,750

(22) Filed: Dec. 14, 2012

(51) Int. Cl. H01L 21/48; H01L 23/538

(52) U.S. Cl. CPC H01L 21/4814; H01L 23/5384
USPC 257/741; 438/687

(57) ABSTRACT

One illustrative device disclosed herein includes a layer of insulating material, a copper-based conductive structure positioned in the layer of insulating material and a bi-layer cap layer comprised of a first layer of material positioned on the copper-based conductive structure and a second layer of material positioned on the first layer of material. One method disclosed herein includes forming a copper-based conductive structure in a first layer of insulating material, forming a first layer of a bi-layer cap layer on the copper-based conductive structure, the first layer being comprised of silicon carbon nitride, forming a second layer of the bi-layer cap layer on the first layer, the second layer being comprised of silicon nitride, and forming a second layer of insulating material above the second layer.

### BACKGROUND OF THE INVENTION

1. Field of the Invention

Generally, the present disclosure relates to the manufacture of sophisticated semiconductor devices, and, more specifically, to various methods of forming a bi-layer cap layer on copper-based conductive structures and to devices that have such a bi-layer cap layer.

2. Description of the Related Art

The fabrication of advanced integrated circuits, such as CPUs, storage devices, ASICs (application specific integrated circuits) and the like, requires a large number of circuit elements, such as transistors, capacitors, resistors, etc., to be formed on a given chip area according to a specified circuit layout. During the fabrication of complex integrated circuits using, for instance, MOS (Metal-Oxide-Semiconductor) technology, millions of transistors, e.g., N-channel transistors (NFETs) and/or P-channel transistors (PFETs), are formed on a substrate including a crystalline semiconductor layer. A field effect transistor, irrespective of whether an NFET transistor or a PFET transistor is considered, typically includes doped source and drain regions that are formed in a semiconducting substrate and separated by a channel region. A gate insulation layer is positioned above the channel region and a conductive gate electrode is positioned above the gate insulation layer. By applying an appropriate voltage to the gate electrode, the channel region becomes conductive and current is allowed to flow from the source region to the drain region.

In a field effect transistor, the conductivity of the channel region, i.e., the drive current capability of the conductive channel, is controlled by a gate electrode formed adjacent to the channel region and separated therefrom by a thin gate insulation layer. The conductivity of the channel region, upon formation of a conductive channel due to the application of an appropriate control voltage to the gate electrode, depends on, among other things, the dopant concentration, the mobility of the charge carriers and, for a given extension of the channel region in the transistor width direction, the distance between the source and drain regions, which is also referred to as the channel length of the transistor. Thus, in modern ultra-high density integrated circuits, device features, like the channel length, have been steadily decreased in size to enhance the performance of the semiconductor device and the overall functionality of the circuit. For example, the gate length (the distance between the source and drain regions) on modern transistor devices may be approximately 30-50 nm and further scaling (reduction in size) is anticipated in the future. This ongoing and continuing decrease in the channel length of transistor devices has improved the operating speed of the transistors and integrated circuits that are formed using such transistors. However, there are certain problems that arise with the ongoing shrinkage of feature sizes that may at least partially offset the advantages obtained by such feature size reduction. For example, as the channel length is decreased, the pitch between adjacent transistors likewise decreases, thereby increasing the density of transistors per unit area. This scaling also limits the size of the conductive contact elements and structures, which has the effect of increasing their electrical resistance. In general, the reduction in feature size and increased packing density makes everything more crowded on modern integrated circuit devices, at both the device level and within the various metallization layers.

Improving the functionality and performance capability of various metallization systems has also become an important aspect of designing modern semiconductor devices. One example of such improvements is reflected in the increased use of copper metallization systems in integrated circuit devices and the use of so-called “low-k” dielectric materials (materials having a dielectric constant less than about 3) in such devices. Copper metallization systems exhibit improved electrical conductivity as compared to, for example, prior metallization systems that used tungsten for the conductive lines and vias. The use of low-k dielectric materials tends to improve the signal-to-noise ratio (S/N ratio) by reducing crosstalk as compared to other dielectric materials with higher dielectric constants. However, the use of such low-k dielectric materials can be problematic as they tend to be less resistant to metal migration as compared to some other dielectric materials.

Copper is a material that is difficult to etch using traditional masking and etching techniques. Thus, conductive copper structures, e.g., conductive lines or vias, in modern integrated circuit devices are typically formed using known single or dual damascene techniques. In general, the damascene technique involves (1) forming a trench/via in a layer of insulating material, (2) depositing one or more relatively thin barrier or liner layers (e.g., TiN, Ta, TaN), (3) forming copper material across the substrate and in the trench/via and (4) performing a chemical mechanical polishing process to remove the excess portions of the copper material and the barrier layer(s) positioned outside of the trench/via to define the final conductive copper structure. The copper material is typically formed by performing an electrochemical copper deposition process after a thin conductive copper seed layer is deposited by physical vapor deposition on the barrier layer.

Typically, after a conductive copper structure is formed in a layer of insulating material, a cap layer is formed above the conductive copper structure. FIGS. 1A-1B depict illustrative examples of prior art capping layers that may be formed on conductive copper structures, e.g., conductive copper lines and/or vias. As shown in FIG. 1A, a device 10 is comprised of a layer of insulating material 11, an illustrative conductive copper structure 12 and a cap layer 14. For clarity, one or more barrier layers that are typically formed between the conductive copper structure 12 and the layer of insulating material 11 are not depicted in FIGS. 1A-1B. In the example depicted in FIG. 1A, the cap layer 14 is comprised of a single layer of silicon carbon nitride (SiCN) that has a thickness within the range of about 10-100 nm. Such a layer of silicon carbon nitride 14 is typically formed by performing a blanket deposition process (with a deposition rate of about 30-200 nm/min) using a plasma-enhanced deposition process, such as a plasma-enhanced chemical vapor deposition process (PECVD). As device dimension are continuing to decrease, the thickness of the cap layer 14 must also decrease. However, in the case where the cap layer 14 is made of silicon carbon nitride, further reductions in its thickness tend to adversely affect its barrier and electrical properties. More specifically, as the thickness of the silicon carbon nitride layer 14 is reduced from the values noted above, its ability to block the penetration of copper and oxygen decreases and it tends to exhibit an undesirable lower breakdown voltage.

FIG. 1B reflects one attempt by the prior art to address the problems noted above when the cap layer 14 was a single layer of silicon carbon nitride. In FIG. 1B, the device 10 includes a cap layer 16 that is made of a single layer of conformally deposited silicon nitride (CSiN) that is formed on the conductive copper structure 12. In one example, the conformally deposited silicon nitride cap layer 16 was formed to a thickness within the range of about 5-25 nm. Such a conformally deposited silicon nitride 16 is typically formed by performing a cyclical conformal deposition process (with a deposition rate of about 10-100 nm/min) using a plasma-enhanced deposition process, such as a plasma-enhanced chemical vapor deposition process (PECVD) or a plasma-enhanced atomic layer deposition process (PEALD). The use of the conformally deposited silicon nitride material as a cap layer has many advantages. For example, it may be readily scaled down in thickness without significantly impacting its electrical and barrier properties. Moreover, the conformally deposited silicon nitride material is more resistant to changes in the stress level of the material when it is exposed to so-called UV curing processes that are performed on layers of insulating material formed above the cap layer 16, a common situation in current-day semiconductor device manufacturing. Thus, the conformally deposited silicon nitride cap layer 16 is better than the silicon carbon nitride cap layer 14 in terms of maintaining more of its pre-UV curing process stress levels and in terms of reducing substrate bowing. However, using such a conformally deposited silicon nitride cap layer 16 is not without its problems. For example, such a conformally deposited silicon nitride cap layer 16 typically exhibits relatively poor electron migration (EM) properties due to the presence of copper in the cap layer 16 near the interface between the cap layer 16 and the conductive copper structure 12. The introduction of copper into the cap layer 16 may be due to the nature of the process used to form the conformally deposited silicon nitride layer 16—a cyclical deposition plasma treatment process where, within each cycle, a thin layer of silicon nitride is formed and then treated with inert gas plasma. This cycle is repeated until desired thickness is achieved.

The present disclosure is directed to various methods of forming a bi-layer cap layer on copper-based conductive structures and to devices that have such a bi-layer cap layer that may solve or at least reduce some or the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to various methods of forming a bi-layer cap layer on copper-based conductive structures and to devices that have such a bi-layer cap layer. One illustrative device disclosed herein includes a layer of insulating material, a copper-based conductive structure positioned in the layer of insulating material and a bi-layer cap layer comprised of a first layer of material comprised of silicon carbon nitride positioned on the copper-based conductive structure and a second layer of material comprised of silicon nitride positioned on the first layer of material.

One illustrative method disclosed herein involves forming a copper-based conductive structure in a first layer of insulating material, forming a first layer of a bi-layer cap layer on the copper-based conductive structure, wherein the first layer is comprised of silicon carbon nitride, forming a second layer of the bi-layer cap layer on the first layer, wherein the second layer is comprised of silicon nitride, and forming a second layer of insulating material above the second layer.

### BRIEF DESCRIPTION OF THE DRAWINGS

The disclosure may be understood by reference to the following description taken in conjunction with the accompanying drawings, in which like reference numerals identify like elements, and in which:

FIGS. 1A-1B depict illustrative examples of prior art cap layers that were formed on copper-based conductive structures; and

FIG. 2 depicts one illustrative embodiment of a novel bi-layer cap layer disclosed herein that is formed on an illustrative copper-based conductive structure.

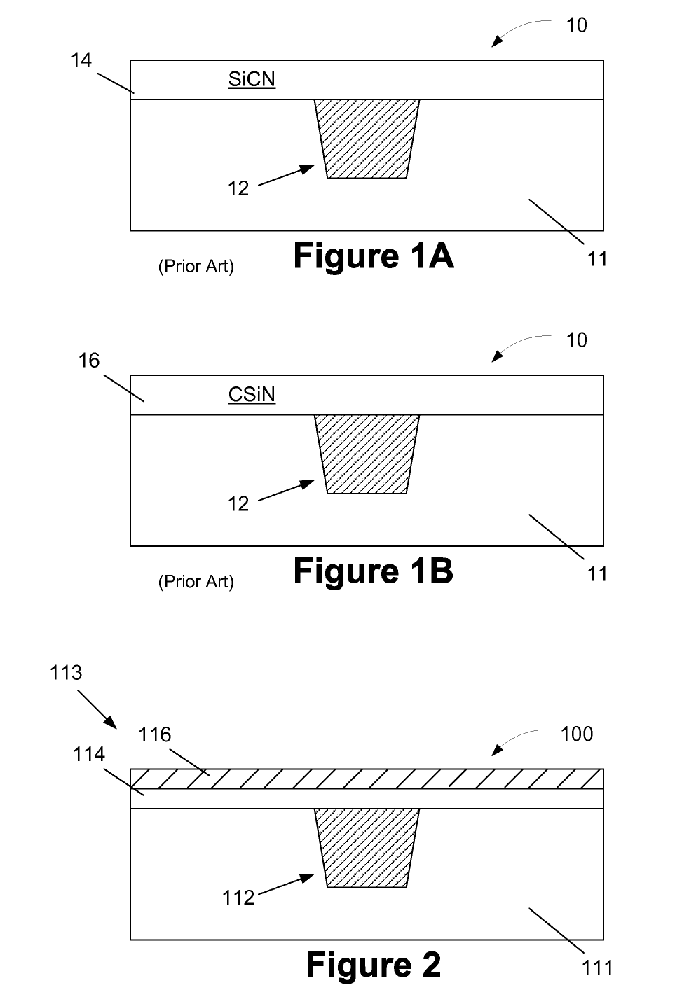

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure is directed to methods of forming a bi-layer cap layer on copper-based conductive structures and to devices that have such a bi-layer cap layer. As will be readily apparent to those skilled in the art upon a complete reading of the present application, the present method is applicable to a variety of technologies, e.g., NFET, PFET, CMOS, etc., and is readily applicable to a variety of devices, including, but not limited to, ASIC's, logic devices, memory devices, etc. With reference to the attached drawings, various illustrative embodiments of the methods disclosed herein will now be described in more detail.

FIG. 2 is a simplified view of an illustrative integrated circuit device 100 at an early stage of manufacturing that is formed above a semiconducting substrate (not shown). The device 100 may be any type of integrated circuit device that employs any type of a conductive copper structure, such as a conductive line or via commonly found on integrated circuit devices. At the point of fabrication depicted in FIG. 2, a bi-layer cap layer 113 comprised of a first layer 114 and a second layer 116 is formed above an illustrative conductive copper structure 112 that is positioned in an illustrative layer of insulating material 111. The conductive copper structure 112 may be of any desired shape, depth or configuration. The conductive copper structure 112 is intended to be representative of any type of conductive feature, e.g., conductive copper lines and or vias that may be formed in any type of semiconductor device and at any level of a semiconductor device. For example, in some embodiments, the conductive copper structure 112 may be a classic line-type feature that does not extend to an underlying layer of material, such as the illustrative conductive copper structure 112 depicted in FIG. 2. In other embodiments, the conductive copper structure 112 may be a through-hole type feature, e.g., a classic via, that extends all of the way through the layer of insulating material 111 and exposes an underlying layer of material (not shown) or an underlying conductive structure (not shown), such as an underlying metal line. Thus, the shape, size, depth or configuration of the conductive copper structure 112 should not be considered to be a limitation of the present invention.

Similarly, the layer of insulating material 111 is intended to be representative of any type of insulating material wherein a conductive copper structure 112 may be formed in a semiconductor device. For example, the layer of insulating material 111 may be comprised of any type of insulating material, e.g., silicon dioxide, a low-k insulating material (k value less than 3), a high-k insulating material (k value greater than 10), etc., it may be formed to any desired thickness and it may be formed by performing, for example, a chemical vapor deposition (CVD) process or an atomic layer deposition (ALD) process, or plasma-enhanced versions of such processes. If necessary, the layer of insulating material 111 may be subjected to a UV cure process after it is initially formed.

With continuing reference to FIG. 2, in one illustrative embodiment, the first layer 114 may be made of a material such as silicon carbon nitride (SiCN), silicon nitride (SiN) or silicon carbon (SiC), and it may have a thickness that falls within the range of about 1-50 nm. In one illustrative embodiment, the first layer 114 may be formed by performing a standard PECVD process or a low-deposition-rate PECVD or PEALD process using a deposition rate that is between about 30-200 nm/minute. The deposition process usually involves inert gas plasma (usually nitrogen, helium and/or argon) and reactive precursors such as ammonia, silane, tri-methyl silane, etc. The resulting film or layer may or may not be subject to subsequent treatment steps in order to modify the properties of the film. The treatment steps may or may not consist of inert gas plasma, with or without reactive gases, and/or ultraviolet exposure. This layer is characterized as an interfacial barrier that maintains clear boundary between copper and dielectrics.

With continuing reference to FIG. 2, in one illustrative embodiment, the second layer 116 may be made of a material such as a conformally deposited silicon nitride (CSiN), and it may have a thickness that falls within the range of about 5-50 nm. In one illustrative embodiment, the second layer 116 may be formed by performing a conformal PECVD or PEALD process using a deposition rate within the range of about 10-100 nm/minute. The deposition process usually involves inert gas plasma (usually nitrogen, helium and/or argon) and reactive precursors such as ammonia, silane, tri-methyl silane, etc. The resulting film or layer may or may not be subject to subsequent treatment steps in order to modify the properties of the film. The treatment steps may or may not consist of inert gas plasma, with or without reactive gases, and/or ultraviolet exposure. This layer is characterized as a bulk barrier and provides conformality that is lacking in the bottom layer (the interfacial barrier).

As will be appreciated by those skilled in the art after a complete reading of the present application, after the bi-layer cap layer 113 is formed, another layer of insulating material (not shown) will be formed above the bi-layer cap layer 113, and one or more conductive structures (not shown) may be formed in this additional layer of insulating material. In some cases, this additional layer of material may be made of a material, such as a low-k insulating material, that may be exposed to a UV cure process to complete the formation of the layer of material. During such a UV cure process, the second layer 116 is more resistant to reducing its, as deposited, level of compressive stress due to the nature of the material, e.g., CSiN, and the manner in which it is formed. The first layer 114 may be made of a material such as SiCN that engages the conductive copper structure 112 and thereby prevents the migration of copper into the second layer 116. By blocking the migration of copper into the second layer 116, the electron migration properties of the CSiN layer 116 may not be degraded, as occurs with the prior art CSiN layer 16 described in the background section of this application.

Testing and simulation results have confirmed that one illustrative bi-layer capping layer disclosed herein provides significant and unexpected performance benefits as compared to either of the single capping layers 14, 16 discussed in the background section of this application. The results are based upon an embodiment of the bi-layer cap layer 113 wherein the first layer 114 is a 10 nm thick SiCN layer and the second layer 116 is a 15 nm thick layer of CSN. Comparisons were made to data relating to a sample of the prior art single layer SiCN cap layer 14 having a thickness of 25 nm and to a sample of the prior art single layer CSiN cap layer 16 having a thickness of 25 nm. In some cases, the first layer 114 was deposited using the low-deposition-rate PECVD process described above.

As noted in the background section of the application, the single SiCN cap layer 14 is generally better at reducing electron migration than is the single CSiN cap layer 16. However, the single CSiN cap layer 16 tends to have better conformality which translates into better device yields. As disclosed herein, in the bi-layer cap layer 113 disclosed herein, the SiCN cap layer 114 is placed in the bottom adjacent the conductive structure to increase reliability (i.e., reduce electron migration), as reliability is predominately determined by the interface between the conducting structure and the SiCN cap layer 114, while the second layer is selected to be CiSN cap layer 116 so as to increase device yields due to its better conformality. The electron migration capabilities of the above-described bi-layer cap layer 113 is approximately the same as that of the single SiCN cap layer 14 or better than that of the single layer CSiN cap layer 16. Additionally, in terms of product yield, the above-described bi-layer cap layer 113 had yields similar to that of the single CSiN layer 16 but better than that of the single SiCN layer 14 because of its better conformality. Lastly, using the above-described bi-layer cap layer 113, the penetration of copper into a cap layer 113 near the interface between the cap layer 113 and the conductive structure 112 was significantly reduced, e.g., by about 95-99%, as compared to a single CSiN layer. The barrier properties of the bi-layer 113 also appear to be about 20-50% better when the second layer 116 is formed using a conformal nitride deposition, as described above. Thus, the novel bi-layer cap layer 113 provides better barrier properties, improves yield, improved conformity, equivalent reliability to the single layer SiCN cap layer 14 and it may be readily scaled as needed to meet the demands of future generations of devices.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A device, comprising
a layer of insulating material;
a copper-based conductive structure positioned in said layer of insulating material; and
a bi-layer cap layer comprised of a first layer of material positioned on said copper-based conductive structure and a second layer of material positioned on said first layer of material.

2. The device of claim 1, wherein said first layer of material is comprised of one of silicon carbon nitride (SiCN), silicon carbon (SiC) or silicon nitride (SiN).

3. The device of claim 2, wherein said second layer of material is comprised of one of silicon nitride (SiN), silicon carbide or silicon carbon nitride.

4. The device of claim 1, wherein said second layer of material is comprised of one of silicon nitride (SiN), silicon carbide or silicon carbon nitride.

5. The device of claim 1, wherein said first layer of material is comprised of silicon carbon nitride (SiCN) and said second layer of material is comprised of silicon nitride (SiN).

6. The device of claim 1, wherein said layer of insulating material is comprised of one of silicon dioxide, a low-k insulating material or a high-k insulating material.

7. The device of claim 1, wherein said copper-based conductive structure is one of a conductive metal line or a conductive metal via.

8. A device, comprising
a layer of insulating material;
a copper-based conductive structure positioned in said layer of insulating material; and
a bi-layer cap layer comprised of a first layer of material comprised of silicon carbon nitride positioned on said copper-based conductive structure and a second layer of material comprised of silicon nitride positioned on said first layer of material.

9. The device of claim 8, wherein said first layer of material has a thickness that falls within the range of about 1-50 nm.

10. The device of claim 9, wherein said second layer of material has a thickness that falls within the range of about 5-50 nm.

11. The device of claim 9, wherein said layer of insulating material is comprised of one of silicon dioxide, a low-k insulating material or a high-k insulating material.

12. The device of claim 11, wherein said copper-based conductive structure is one of a conductive metal line or a conductive metal via.

13. A method, comprising:
forming a copper-based conductive structure in a first layer of insulating material;
forming a first layer of a bi-layer cap layer on said copper-based conductive structure;
forming a second layer of said bi-layer cap layer on said first layer; and
forming a second layer of insulating material above said second layer.

14. The method of claim 13, wherein forming said first layer of said bi-layer cap layer comprises performing a plasma-based deposition process to form said first layer, wherein a deposition rate during said deposition process is at least 30 nm/min or greater.

15. The method of claim 14, wherein said plasma-based deposition process is a PECVD process.

16. The method of claim 13, wherein forming said first layer of said bi-layer cap layer comprises performing a low-deposition-rate plasma-based deposition process to form said first layer, wherein a deposition rate during said low-deposition-rate plasma-based deposition process is less than or equal to about 100 nm/min.

17. The method of claim 16, wherein said low-deposition-rate plasma-based deposition process is one of a PECVD process or a PEALD process.

18. The method of claim 13, wherein forming said first layer of said bi-layer cap layer comprises forming said first layer from one of silicon carbon nitride (SiCN), silicon carbon (SiC) or silicon nitride (SiN).

19. The method of claim 18, wherein forming said second layer of said bi-layer cap layer comprises forming said second layer from one of silicon nitride (SiN), silicon carbide or silicon carbon nitride.

20. The method of claim 13, wherein forming said second layer of said bi-layer cap layer comprises forming said second layer from one of silicon nitride (SiN), silicon carbide or silicon carbon nitride.

21. The method of claim 13, wherein forming said second layer of said bi-layer cap layer comprises performing a plasma-based deposition process to form said second layer, wherein a deposition rate during said deposition process is at least 30 nm/min or greater.

22. A method, comprising:
forming a copper-based conductive structure in a first layer of insulating material;
forming a first layer of a bi-layer cap layer on said copper-based conductive structure, said first layer being comprised of silicon carbon nitride;
forming a second layer of said bi-layer cap layer on said first layer, said second layer being comprised of silicon nitride; and
forming a second layer of insulating material above said second layer.

23. The method of claim 22, wherein forming said first layer of said bi-layer cap layer comprises performing a plasma-based deposition process to form said first layer, wherein a deposition rate during said deposition process is at least 30 nm/min or greater.

24. The method of claim 22, wherein forming said first layer of said bi-layer cap layer comprises performing a low-deposition-rate plasma-based deposition process to form said first layer, wherein a deposition rate during said low-deposition-rate plasma-based deposition process is less than or equal to about 100 nm/min.

25. The method of claim 22, wherein forming said second layer of said bi-layer cap layer comprises performing a plasma-based deposition process to form said second layer, wherein a deposition rate during said deposition process is at least 30 nm/min or greater.

26. A method, comprising:
forming a copper-based conductive structure in a first layer of insulating material;
performing a first low-deposition-rate plasma-based deposition process to form a first layer of a bi-layer cap layer on said copper-based conductive structure, wherein said first layer is comprised of silicon carbon nitride and wherein a deposition rate during said first low-deposition-rate plasma-based deposition process is less than or equal to about 100 nm/min;
performing a second plasma-based deposition process to form a second layer of a bi-layer cap layer on said first layer, wherein said second layer is comprised of silicon nitride and wherein a deposition rate during said second plasma-based deposition process is at least 30 nm/min or greater; and
forming a second layer of insulating material above said second layer.
